(19) United States
(12) Patent Application Publication
(10) Pub. No.: US 2025/0174407 A1
(43) Pub. Date: May 29, 2025

(54) ELECTRONIC COMPONENT

(71) Applicant: Murata Manufacturing Co., Ltd., Kyoto-fu (JP)

(72) Inventors: Hisaki KITAGAWA, Nagaokakyo-shi (JP); Masayuki AOIKE, Nagaokakyo-shi (JP)

(73) Assignee: Murata Manufacturing Co., Ltd., Kyoto-fu (JP)

(21) Appl. No.: 18/953,947

(22) Filed: Nov. 20, 2024

(30) Foreign Application Priority Data
Nov. 29, 2023 (JP) 2023-201988

(51) Int. Cl. H01G 4/33; H01G 4/008; H01G 4/224; H01L 23/00; H01L 25/16

(52) U.S. Cl. CPC H01G 4/33; H01G 4/008; H01G 4/224; H01L 24/48; H01L 25/16; H10D 1/696; H01L 2224/48195; H01L 2924/1205

(57) ABSTRACT

An electronic component includes a thin-film capacitor including a lower electrode disposed on a first surface that is a surface of a substrate, a capacitor dielectric film disposed on the lower electrode, and an upper electrode disposed on the capacitor dielectric film. An insulating resin film is disposed on the first surface so as to cover the thin-film capacitor. The upper electrode includes two layers that are a titanium film primarily including Ti and a platinum film primarily including Pt. The platinum film is interposed between the titanium film and the resin film.

### CROSS-REFERENCE TO RELATED APPLICATION

This application claims benefit of priority to Japanese Patent Application No. 2023-201988, filed Nov. 29, 2023, the entire content of which is incorporated herein by reference.

### BACKGROUND

### Technical Field

The present disclosure relates to an electronic component.

### Background Art

Thin-film capacitors, such as MIM capacitors, have been used for compact electronic devices as described, for example, in Japanese Unexamined Patent Application Publication No. 2010-109014. A thin-film capacitor is constituted by a lower electrode, a capacitor dielectric film, and an upper electrode that are disposed on and above a substrate. The thin-film capacitor disclosed in Japanese Unexamined Patent Application Publication No. 2010-109014 is covered with an insulating hydrogen barrier film composed of Al₂O₃, TiO₂, Ta₂O₅, SiN, or the like and an insulating film composed of Al₂O₃, SiO₂, or the like.

### SUMMARY

In the case where an electronic circuit is disposed on an insulating film that covers a thin-film capacitor, it is preferable to planarize the upper surface of the insulating film. Moreover, it is desirable to reduce the stray capacitance between the thin-film capacitor and the electronic circuit disposed on the insulating film. Accordingly, the present disclosure provides an electronic component in which an insulating film covering a thin-film capacitor may be planarized and the stray capacitance may be reduced.

According to an aspect of the present disclosure, an electronic component includes a substrate; a thin-film capacitor including a lower electrode disposed on a first surface, the first surface being a surface of the substrate, a capacitor dielectric film disposed on the lower electrode, and an upper electrode disposed on the capacitor dielectric film; and an insulating resin film disposed on the first surface so as to cover the thin-film capacitor. The upper electrode includes two layers, the two layers being a titanium film primarily including Ti and a platinum film primarily including Pt. The platinum film can be interposed between the titanium film and the resin film.

When the thin-film capacitor is covered with the resin film, the upper surface of the resin film can be readily planarized compared with the case where the thin-film capacitor is covered with an insulating film composed of an inorganic insulating material. In addition, since an insulating resin commonly has lower dielectric permittivity than an inorganic insulating material, the stray capacitance between the thin-film capacitor and an electronic circuit disposed on the resin film may be reduced. Furthermore, the platinum film serves as a barrier film that reduces the entry of the moisture included in the resin film into the titanium film. This may reduce the entry of the moisture into the capacitor dielectric film and limit the degradation of the capacitor dielectric film.

### BRIEF DESCRIPTION OF THE DRAWINGS

FIG. 1 is a cross-sectional view of an electronic component according to a first example;

FIG. 2 is a cross-sectional view of an electronic component according to a second example;

FIGS. 3A to 3D are cross-sectional views of the electronic component according to the second example, illustrating the steps for producing the electronic component;

FIG. 4 is a cross-sectional view of an electronic component according to a third example;

FIG. 5 is a cross-sectional view of an electronic component according to a fourth example;

FIG. 6 is a cross-sectional view of an electronic component according to a fifth example;

FIG. 7 is a cross-sectional view of an electronic component according to a sixth example;

FIG. 8 is a cross-sectional view of an electronic component according to a seventh example;

FIG. 9 is a diagram illustrating the positional relationship between first and second openings formed in the electronic component according to the seventh example in a plan view; and

FIG. 10 is a cross-sectional view of an electronic component according to an eighth example.

### DETAILED DESCRIPTION

### First Example

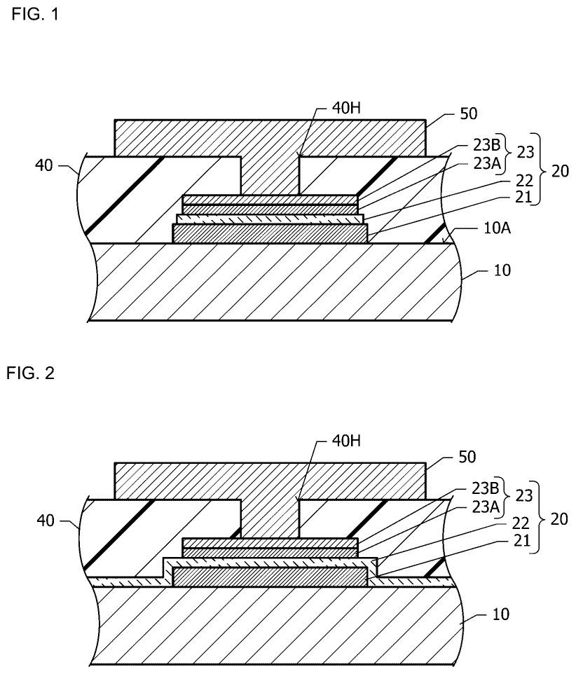

An electronic component according to a first example is described with reference to FIG. 1.

FIG. 1 is a cross-sectional view of the electronic component according to the first example. A thin-film capacitor 20 is disposed on an insulative surface (hereinafter, referred to as “first surface 10A”) of a substrate 10 having an insulative surface-layer portion. The thin-film capacitor 20 includes a lower electrode 21 disposed on the first surface 10A, a capacitor dielectric film 22 disposed on the lower electrode 21, and an upper electrode 23 disposed on the capacitor dielectric film 22. The capacitor dielectric film 22 may be constituted by a plurality of dielectric films composed of different dielectric materials.

When the first surface 10A is viewed in a plan view (hereinafter, may be referred to as “in a plan view”), the capacitor dielectric film 22 is included in the lower electrode 21. The upper electrode 23 is included in the capacitor dielectric film 22 in a plan view.

An insulating resin film 40 is disposed on the first surface 10A so as to cover the thin-film capacitor 20. The upper surface of the resin film 40 is substantially planarized. The resin film 40 has a first opening 40H formed therein, at which the upper electrode 23 is partially exposed. A wire 50 is disposed on the resin film 40. The wire 50 is connected to the upper electrode 23 through the first opening 40H.

A compound semiconductor substrate, such as a semi-insulating GaAs substrate, is used as a substrate 10. Alternatively, a GaN substrate, an InP substrate, a SiC substrate, and the like may be used. A Si substrate may also be used instead of a compound semiconductor substrate.

The lower electrode 21 is composed of a metal material, such as Au, Ti, Pt, W, Al, Mo, or Cr. The capacitor dielectric film 22 is composed of silicon nitride (SiN) or the like. The upper electrode 23 is constituted by a titanium film 23A and a platinum film 23B. Note that the term “titanium film” used herein refers to a film composed of a metal material primarily including Ti, and the term “platinum film” used herein refers to a film composed of a metal material primarily including Pt. For example, when a Ti content is 10 atomic % or more, it can be said that “primarily includes Ti”. When a Pt content is 10 atomic % or more, it can be said that “primarily includes Pt”. The platinum film 23B is interposed between the titanium film 23A and the resin film 40. In a plan view, the titanium film 23A and the platinum film 23B have the same shape and the same size and arranged to be substantially superimposed on top of each other. The upper electrode 23 may have a single-layer structure or a multilayer structure constituted by three or more layers. The lower electrode 21 may be constituted by two or more conductive films composed of different conductive materials.

The resin film 40 is composed of an insulating resin, such as a polyimide resin, an epoxy resin, a benzocyclobutene (BCB) resin, or a polybenzoxazole (PBO) resin. The resin film 40 may be formed by coating or the like. The wire 50 is composed of Cu or the like.

The advantageous effects of the first example are described below.

In the first example, the thin-film capacitor 20 is covered with the resin film 40. The upper surface of the resin film 40 can be readily planarized compared with an insulating film composed of an inorganic insulating material. Planarizing the upper surface of the resin film 40 enables reductions in the sizes of electronic circuits disposed above the resin film 40, such as the wire 50.

The insulating resin constituting the resin film 40 commonly has lower dielectric permittivity than an inorganic insulating material, such as Al₂O₃, SiN, or SiO₂. This enables a reduction in the stray capacitance between the thin-film capacitor 20 and an electronic circuit disposed on the resin film 40.

Ti, which is included in the upper electrode 23, is highly reactive with moisture. If the titanium film 23A included in the upper electrode 23 comes into contact with the resin film 40, the moisture included in the resin film 40 enters the titanium film 23A and reaches the capacitor dielectric film 22 through the titanium film 23A. If the moisture enters the capacitor dielectric film 22, the degradation of the capacitor dielectric film 22 is accelerated. In the first example, the platinum film 23B serves as a barrier film that reduces the entry of moisture included in the resin film 40 into the titanium film 23A. This also reduces the entry of the moisture into the capacitor dielectric film 22 and limits the degradation of the capacitor dielectric film 22. In order to allow the platinum film 23B to serve as a barrier film in a sufficient manner, the thickness of the platinum film 23B is preferably about 5 nm or more. The titanium film 23A increases the adhesion between the upper electrode 23 and the capacitor dielectric film 22.

### Second Example

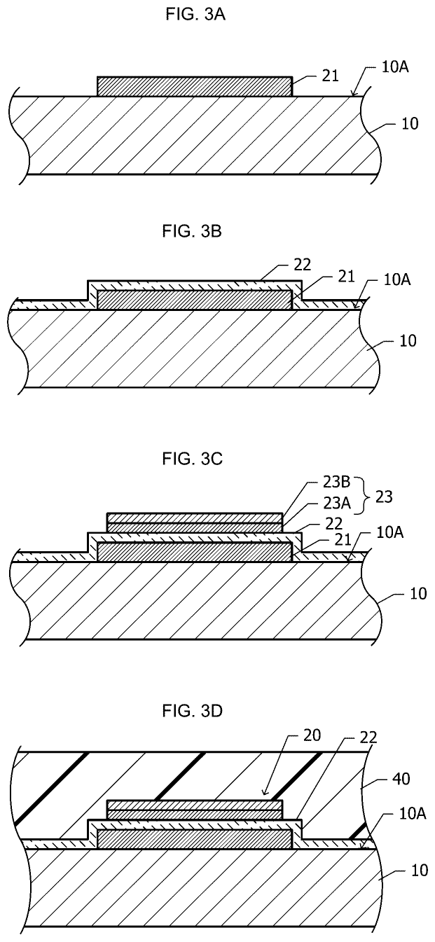

An electronic component according to a second example is described with reference to FIGS. 2 and 3A to 3D below. Hereinafter, the description of structures that are the same as those included in the electronic component according to the first example, which is described with reference to FIG. 1, is omitted.

FIG. 2 is a cross-sectional view of the electronic component according to the second example. In the first example (FIG. 1), in a plan view, the capacitor dielectric film 22 is included in the lower electrode 21. In the second example, in contrast, the capacitor dielectric film 22 is arranged to extend to the outer side portion of the lower electrode 21 in a plan view and covers the side surface of the lower electrode 21.

A method for producing the electronic component according to the second example is described with reference to FIGS. 3A to 3D below. FIGS. 3A to 3D are cross-sectional views of the electronic component according to the second example, illustrating the steps for producing the electronic component

As illustrated in FIG. 3A, a lower electrode 21 is formed on a first surface 10A of a substrate 10. The lower electrode 21 may be formed using a lift-off method. Alternatively, a photoetching process may be used. A thin-film composed of a metal material which constitutes the lower electrode 21 may be formed by vapor deposition.

As illustrated in FIG. 3B, a capacitor dielectric film 22 is formed on the first surface 10A so as to cover the lower electrode 21. The capacitor dielectric film 22 may be formed using chemical vapor deposition (CVD) or the like. Subsequently, an unnecessary portion of the capacitor dielectric film 22 is etched by a photoetching process. It is not necessary to perform the above etching in the case where the capacitor dielectric film 22 is left all over the first surface 10A. Depending on the range in which the etching is done, a capacitor dielectric film 22 that is included in the lower electrode 21 in a plan view may be formed as in the first example (FIG. 1).

As illustrated in FIG. 3C, an upper electrode 23 having a multilayer structure constituted by a titanium film 23A and a platinum film 23B is formed on the capacitor dielectric film 22. The upper electrode 23 may be formed using a lift-off method or the like. Alternatively, a photoetching process may be used.

As illustrated in FIG. 3D, a resin film 40 is formed all over the first surface 10A so as to cover the thin-film capacitor 20. The resin film 40 may be formed using coating or the like.

A first opening 40H is formed in the resin film 40 as illustrated in FIG. 2. The first opening 40H may be formed by, for example, using a photosensitive resin material as a material for the resin film 40 and subsequently performing exposure and developing. Subsequently, a wire 50 is formed on the resin film 40. The wire 50 may be formed using a lift-off method.

The advantageous effects of the second example are described below.

In the second example, the same advantageous effects as in the first example are produced. Moreover, since the upper and side surfaces of the lower electrode 21 are covered with the capacitor dielectric film 22 in the second example, the entry of the moisture included in the resin film 40 into the lower electrode 21 may be reduced. In order to allow the capacitor dielectric film 22 to serve as a barrier film that reduces the entry of the moisture in a sufficient manner, it is preferable to form the capacitor dielectric film 22 using silicon nitride, which is chemically more stable than silicon oxide.

### Third Example

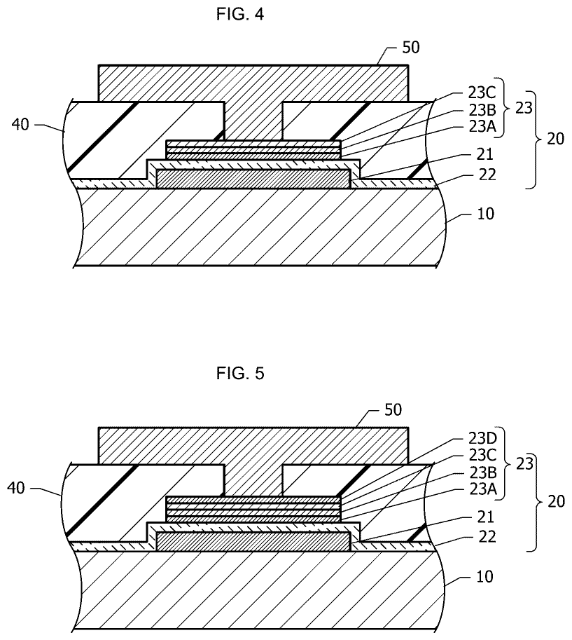

An electronic component according to a third example is described with reference to FIG. 4 below. Hereinafter, the description of structures that are the same as those included in the electronic components according to the first and second examples, which are described with reference to FIGS. 1 and 3A to 3D, is omitted.

FIG. 4 is a cross-sectional view of the electronic component according to the third example. In the first example (FIG. 1) and the second example (FIG. 2), the upper electrode 23 is constituted by two layers, that is, the titanium film 23A and the platinum film 23B. In contrast, in the third example, the upper electrode 23 further includes a gold film 23C disposed on the platinum film 23B. The gold film 23C primarily includes Au. For example, when a Au content is 10 atomic % or more, it can be said that “primarily includes Au”.

The advantageous effects of the third example are described below.

Since the upper electrode 23 includes the gold film 23C in the third example, the sheet resistance of the upper electrode 23 may be reduced compared with the case where the upper electrode 23 is constituted by two layers, that is, the titanium film 23A and the platinum film 23B. In addition, when the gold film 23C and the titanium film 23A are arranged in contact with each other, titanium may be diffused at the grain boundaries of the gold film 23C by the heat transmitted during the production process. In the third example, the platinum film 23B is interposed between the titanium film 23A and the gold film 23C. The platinum film 23B serves as a barrier film that limits the diffusion of titanium into the gold film 23C. Consequently, the diffusion of titanium into the gold film 23C may be limited.

### Fourth Example

An electronic component according to a fourth example is described with reference to FIG. 5 below. Hereinafter, the description of structures that are the same as those included in the electronic component according to the third example, which is described with reference to FIG. 4, is omitted.

FIG. 5 is a cross-sectional view of the electronic component according to the fourth example. In the fourth example (FIG. 4), the upper surface of the gold film 23C included in the upper electrode 23 is in contact with the resin film 40. In contrast, in the fourth example, a titanium film 23D is interposed between the gold film 23C and the resin film 40.

The advantageous effects of the fourth example are described below.

The adhesiveness between the titanium film 23D and the resin film 40 is higher than the adhesiveness between the gold film 23C and the resin film 40. Since the titanium film 23D is interposed between the gold film 23C and the resin film 40 in the fourth example, the adhesiveness between the upper electrode 23 and the resin film 40 may be increased.

In the fourth example, although the platinum film 23B is interposed between the lower titanium film 23A and the gold film 23C in order to limit the diffusion of Ti into the gold film 23C, a platinum film is not interposed between the gold film 23C and the upper titanium film 23D. Even in this structure, the platinum film 23B interposed between the lower titanium film 23A and the gold film 23C limits the entry of the moisture included in the resin film 40 into the capacitor dielectric film 22. Therefore, the degradation of the capacitor dielectric film 22 may be advantageously limited in a sustained manner.

### Fifth Example

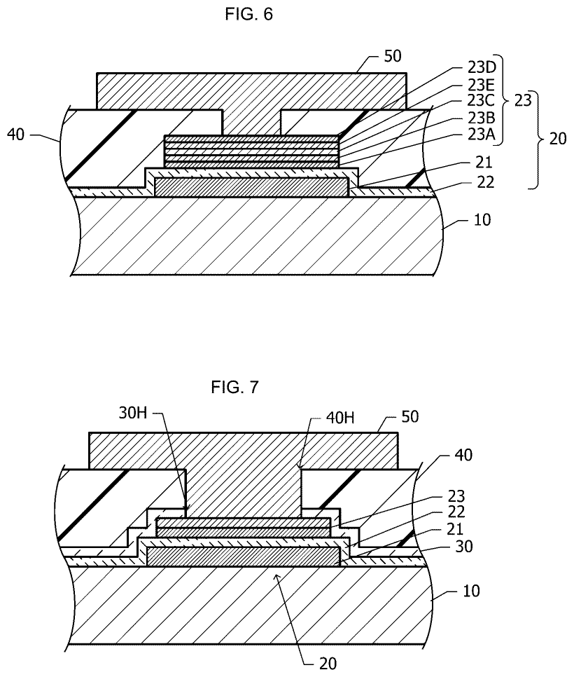

An electronic component according to a fifth example is described with reference to FIG. 6 below. Hereinafter, the description of structures that are the same as those included in the electronic component according to the fourth example, which is described with reference to FIG. 5, is omitted.

FIG. 6 is a cross-sectional view of the electronic component according to the fifth example. In the fourth example (FIG. 5), a platinum film is not interposed between the gold film 23C and the upper titanium film 23D. In contrast, in the fifth example, an upper platinum film 23E is interposed between the gold film 23C and the upper titanium film 23D.

The advantageous effects of the fifth example are described below. In the fifth example, the upper platinum film 23B limits the diffusion of titanium included in the upper titanium film 23D into the gold film 23C. This enhances the advantageous effect of reducing the entry of the moisture included in the resin film 40 into the capacitor dielectric film 22.

### Sixth Example

An electronic component according to a sixth example is described with reference to FIG. 7 below. Hereinafter, the description of structures that are the same as those included in the electronic component according to the second example, which is described with reference to FIGS. 2 and 3A to 3D, is omitted.

FIG. 7 is a cross-sectional view of the electronic component according to the sixth example. In the second example (FIG. 2), the upper electrode 23 and the capacitor dielectric film 22, which are included in the thin-film capacitor 20, are arranged to come into contact with the resin film 40. In contrast, in the sixth example, an inorganic insulating film 30 composed of an inorganic insulating material is interposed between the upper electrode 23 and the resin film 40.

The inorganic insulating film 30 is arranged to extend to the region in which the capacitor dielectric film 22 is disposed and is also interposed between the capacitor dielectric film 22 and the resin film 40. The inorganic insulating film 30 may be composed of silicon oxide, silicon oxynitride, silicon nitride, aluminum oxide, or the like. The inorganic insulating film 30 has a second opening 30H formed therein, which has substantially the same shape and substantially the same size as the first opening 40H formed in the resin film 40. A wire 50 is connected to the upper electrode 23 through the first opening 40H and the second opening 30H.

A method for producing the electronic component according to the sixth example is described below. After the upper electrode 23 has been formed as illustrated in FIG. 3C and before the resin film 40 is formed as illustrated in FIG. 3D, an inorganic insulating film 30 is formed by CVD or the like. After the inorganic insulating film 30 has been formed, a resin film 40 is formed and a first opening 40H is formed in the resin film 40. Then, a second opening 30H is formed in the inorganic insulating film 30. When the second opening 30H is formed in the inorganic insulating film 30, the resin film 40 may be used as an etching mask.

The advantageous effects of the sixth example are described below. In the sixth example, the moisture included in the resin film 40 does not come into direct contact with the upper electrode 23, the capacitor dielectric film 22, and the lower electrode 21, which constitute the thin-film capacitor 20. Since the inorganic insulating film 30 reduces the entry of the moisture included in the resin film 40 into the thin-film capacitor, the moisture resistance of the electronic component may be enhanced.

### Seventh Example

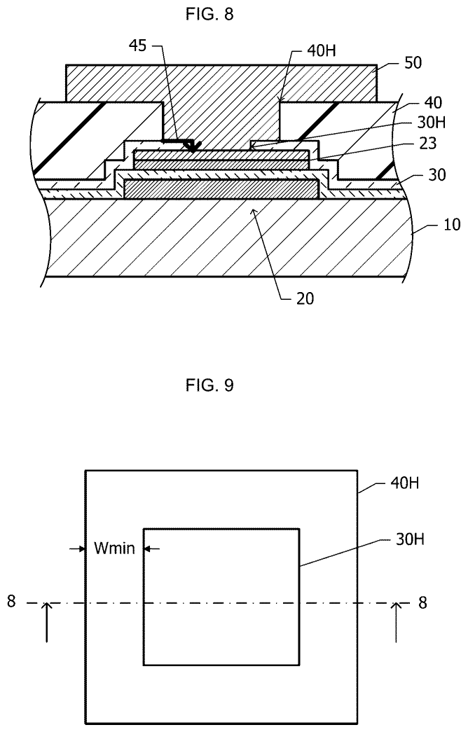

An electronic component according to a seventh example is described with reference to FIGS. 8 and 9 below. Hereinafter, the description of structures that are the same as those included in the electronic component according to the sixth example (FIG. 7) is omitted.

FIG. 8 is a cross-sectional view of the electronic component according to the seventh example. In the sixth example (FIG. 7), the first opening 40H formed in the resin film 40 and the second opening 30H formed in the inorganic insulating film 30 have substantially the same shape and size and are arranged to be substantially superimposed on each other in a plan view. In contrast, in the seventh example, in a plan view, the second opening 30H is smaller than the first opening 40H, and the second opening 30H is included in the first opening 40H.

A method for producing the electronic component according to the seventh example is described below. After the upper electrode 23 has been formed as illustrated in FIG. 3C and before the resin film 40 is formed as illustrated in FIG. 3D, an inorganic insulating film 30 is formed by CVD or the like. Subsequently, a second opening 30H is formed in the inorganic insulating film 30 by a photoetching process. Then, a resin film 40 is formed, and a first opening 40H is formed in the resin film 40. The resin film 40 may be formed before the second opening 30H is formed in the inorganic insulating film 30. In such a case, after the first opening 40H has been formed in the resin film 40, the second opening 30H is formed in a portion of the inorganic insulating film 30 which is exposed at the bottom of the first opening 40H.

FIG. 9 is a diagram illustrating the positional relationship between first and second openings 40H and 30H formed in the electronic component according to the seventh example in a plan view. A cross-sectional view taken along the dash-dotted line 8-8 in FIG. 9 corresponds to FIG. 8. In a plan view, the second opening 30H is included in the first opening 40H.

The advantageous effects of the seventh example are described below. In the seventh example, the moisture included in the resin film 40 migrates from the edge of the first opening 40H to the edge of the second opening 30H along the interface between the inorganic insulating film 30 and the wire 50 as denoted with an arrow 45 in FIG. 8, subsequently migrates downward along the side surface of the second opening 30H, and reaches the upper electrode 23. Therefore, the length of the path along which the moisture reaches the upper electrode 23 is increased compared with the structure according to the sixth example (FIG. 7). As a result of the length of the path of the moisture being increased, the likelihood of the moisture reaching the upper electrode 23 is reduced. This enables moisture resistance to be enhanced.

In order to enhance moisture resistance in a sufficient manner, it is preferable that, in a plan view, the minimum distance Wmin between the edge of the second opening 30H to the edge of the first opening 40H be larger than the thickness of the inorganic insulating film 30.

A modification of the seventh example is described below.

Although the second opening 30H is included in the first opening 40H in a plan view in the seventh example, it is not always necessary that the whole edge of the first opening 40H be located outside the second opening 30H; at least a part of the edge of the first opening 40H may be located outside the second opening 30H. Even in the above structure, the length of the path along which the moisture enters from the edge of the first opening 40H, which is located outside the second opening 30H in a plan view, is increased. This enables moisture resistance to be enhanced compared with the structure according to the sixth example (FIG. 7).

### Eighth Example

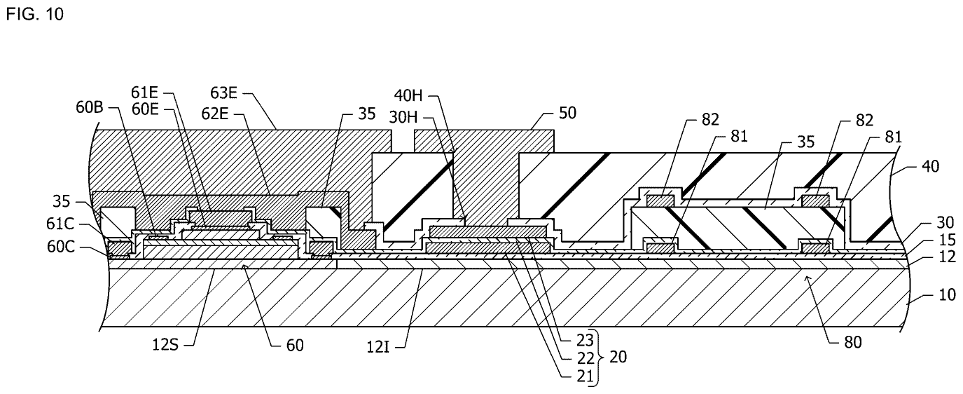

An electronic component according to an eighth example is described with reference to FIG. 10 below. Hereinafter, the description of structures that are the same as those included in the electronic component according to the second example, which is described with reference to FIGS. 2 and 3A to 3D, is omitted.

FIG. 10 is a cross-sectional view of the electronic component according to the eighth example. The electronic component according to the second example (FIG. 2) includes a thin-film capacitor 20 disposed on a substrate 10. In contrast, the electronic component according to the eighth example includes, in addition to the thin-film capacitor 20, electronic circuit elements, such as a heterojunction bipolar transistor 60 and an inductor 80.

An epitaxial growth layer 12 composed of n-type GaAs is disposed on a substrate 10 composed of semi-insulating GaAs. An element isolation region 12I, the resistance of which has been increased by ion implantation, is formed in a portion of the epitaxial growth layer 12. As a result, an n-type subcollector layer 12S surrounded by the element isolation region 12I is defined. A heterojunction bipolar transistor 60 is disposed on the subcollector layer 12S.

The heterojunction bipolar transistor 60 includes a collector layer, a base layer, and an emitter layer stacked on and above the subcollector layer 12S in order. A collector electrode 60C is disposed on the subcollector layer 12S. The collector electrode 60C is connected to a collector layer of the heterojunction bipolar transistor 60 with the subcollector layer 12S. A base electrode 60B is disposed on the base layer. An emitter electrode 60E is disposed on the emitter layer.

An insulating film 15 is disposed all over the upper surface of the substrate 10 so as to cover the heterojunction bipolar transistor 60, the collector electrode 60C, the base electrode 60B, and the emitter electrode 60E. A thin-film capacitor 20 and an inductor 80 are disposed on the insulating film 15.

A plurality of metal patterns, which constitute a first wiring layer, are formed on the insulating film 15. A collector wire 61C and an emitter wire 61E, which are disposed in the first wiring layer, are connected to the collector electrode 60C and the emitter electrode 60E, respectively, through openings formed in the insulating film 15. Moreover, a lower electrode 21 of the thin-film capacitor 20 and a wire 81 constituting a part of the inductor 80 are disposed in the first wiring layer. Although the lower electrode 21 is disposed directly on the first surface 10A of the substrate 10 in the first example (FIG. 1), the lower electrode 21 may be disposed indirectly above the substrate 10 with another film (e.g., an epitaxial growth layer 12 or an insulating film 15) disposed on the substrate 10 being interposed therebetween as in the eighth example.

The capacitor dielectric film 22 that covers the lower electrode 21 covers another metal pattern included in the first wiring layer, such as the collector wire 61C, the emitter wire 61E, or the wire 81 of the inductor 80. An insulating film 35 composed of an insulating resin is disposed in a region that overlaps the collector wire 61C and the wire 81 of the inductor 80 in a plan view.

A plurality of metal patterns, which constitute a second wiring layer, are formed on the capacitor dielectric film 22 and the insulating film 35. For example, an emitter wire 62E, an upper electrode 23, and a wire 82 constituting a part of the inductor 80 are disposed in the second wiring layer. The emitter wire 62E included in the second layer is connected to the emitter wire 61E of the first layer through the opening formed in the capacitor dielectric film 22. The wire 82 included in the second layer, which constitutes the inductor 80, is connected to the wire 81 of the first layer through the opening (formed at a position other than the cross section illustrated in FIG. 10) formed in the insulating film 35 and the capacitor dielectric film 22.

An inorganic insulating film 30 is disposed on the second wiring layer, and a resin film 40 is disposed thereon. A plurality of metal patterns constituting the third wiring layer is disposed on the resin film 40. The third wiring layer includes an emitter wire 63E, a wire 50, and the like. The emitter wire 63E included in the third layer is connected to the emitter wire 62E of the second layer through the opening formed in the resin film 40 and the inorganic insulating film 30. The wire 50 is connected to the upper electrode 23 of the thin-film capacitor 20 through a first opening 40H formed in the resin film 40 and a second opening 30H formed in the inorganic insulating film 30.

The thin-film capacitor 20 is connected to electronic circuit elements, such as the heterojunction bipolar transistor 60 and the inductor 80, with wires included in the first to third wiring layers.

The advantageous effects of the eighth example are described below.

Advantageous effects that are similar to those produced in the first to seventh examples may be produced even in an electronic component that includes, in addition to the thin-film capacitor 20, electronic circuit elements, such as the heterojunction bipolar transistor 60 and the inductor 80, in an integrated manner.

It is needless to say that the above examples are illustrative and the structures described in different examples can be partially replaced or combined with one another. The same actions and effects of the same structures described in a plurality of examples are not described in every example. The present disclosure is not limited by the above examples. For example, various alternations, modifications, and combinations will be apparent to those skilled in the art.

The following items are disclosed on the basis of the examples described herein.

<1> An electronic component including a substrate; a thin-film capacitor including a lower electrode disposed on a first surface, the first surface being a surface of the substrate, a capacitor dielectric film disposed on the lower electrode, and an upper electrode disposed on the capacitor dielectric film; and an insulating resin film disposed on the first surface so as to cover the thin-film capacitor. The upper electrode includes two layers, the two layers being a titanium film primarily including Ti and a platinum film primarily including Pt. The platinum film is interposed between the titanium film and the resin film.

<2> The electronic component according to <1>, wherein the upper electrode further includes a gold film primarily including Au, the gold film being interposed between the platinum film and the resin film.

<3> The electronic component according to <1> or <2>, further including an inorganic insulating film interposed between the upper electrode and the resin film, the inorganic insulating film including an inorganic insulating material.

<4> The electronic component according to <3>, further including a wire disposed on the resin film, the wire being connected to the upper electrode through a first opening formed in the resin film and a second opening formed in the inorganic insulating film. Also, when the first surface is viewed in a plan view, at least a part of an edge of the first opening is located outside the second opening.

<5> The electronic component according to <4>, wherein, when the first surface is viewed in a plan view, the second opening is included in the first opening, and a minimum distance between an edge of the second opening and the edge of the first opening is larger than a thickness of the inorganic insulating film.

<6> The electronic component according to <4> or <5>, further including an electronic circuit element disposed in a region of the first surface, the region in which the thin-film capacitor is not disposed, the electronic circuit element being connected to the thin-film capacitor with the wire.

<7> The electronic component according to any one of <1> to <6>, wherein, when the first surface is viewed in a plan view, at least a part of an edge of the lower electrode is located outside the upper electrode.

<8> The electronic component according to any one of <1> to <7>, wherein the capacitor dielectric film includes silicon nitride and covers a side surface of the lower electrode.

<9> The electronic component according to any one of <1> to <8>, wherein the platinum film has a thickness of about 5 nm or more.

What is claimed is:

1. An electronic component comprising:
a substrate;
a thin-film capacitor including
a lower electrode on a first surface which is a surface of the substrate,
a capacitor dielectric film on the lower electrode, and
an upper electrode on the capacitor dielectric film; and
an insulating resin film on the first surface to cover the thin-film capacitor,
the upper electrode including two layers, the two layers being a titanium film primarily including Ti and a platinum film primarily including Pt,
the platinum film being interposed between the titanium film and the resin film.

2. The electronic component according to claim 1, wherein
the upper electrode further includes a gold film primarily including Au, the gold film being interposed between the platinum film and the resin film.

3. The electronic component according to claim 1, further comprising:
an inorganic insulating film interposed between the upper electrode and the resin film, the inorganic insulating film including an inorganic insulating material.

4. The electronic component according to claim 3, further comprising:
a wire on the resin film,
the wire being connected to the upper electrode through a first opening in the resin film and a second opening in the inorganic insulating film,
wherein, when the first surface is viewed in a plan view, at least a part of an edge of the first opening is outside the second opening.

5. The electronic component according to claim 4, wherein
when the first surface is viewed in a plan view, the second opening is included in the first opening, and
a minimum distance between an edge of the second opening and the edge of the first opening is larger than a thickness of the inorganic insulating film.

6. The electronic component according to claim 4, further comprising:
an electronic circuit element in a region of the first surface, the region being where the thin-film capacitor is absent, and the electronic circuit element being connected to the thin-film capacitor with the wire.

7. The electronic component according to claim 1, wherein
when the first surface is viewed in a plan view, at least a part of an edge of the lower electrode is outside the upper electrode.

8. The electronic component according to claim 1, wherein
the capacitor dielectric film includes silicon nitride and covers a side surface of the lower electrode.

9. The electronic component according to claim 1, wherein
the platinum film has a thickness of about 5 nm or more.

10. The electronic component according to claim 2, further comprising:
an inorganic insulating film interposed between the upper electrode and the resin film, the inorganic insulating film including an inorganic insulating material.

11. The electronic component according to claim 10, further comprising:
a wire on the resin film,
the wire being connected to the upper electrode through a first opening in the resin film and a second opening in the inorganic insulating film,
wherein, when the first surface is viewed in a plan view, at least a part of an edge of the first opening is outside the second opening.

12. The electronic component according to claim 11, wherein
when the first surface is viewed in a plan view, the second opening is included in the first opening, and
a minimum distance between an edge of the second opening and the edge of the first opening is larger than a thickness of the inorganic insulating film.

13. The electronic component according to claim 11, further comprising:
an electronic circuit element in a region of the first surface, the region being where the thin-film capacitor is absent, and the electronic circuit element being connected to the thin-film capacitor with the wire.

14. The electronic component according to claim 2, wherein
when the first surface is viewed in a plan view, at least a part of an edge of the lower electrode is outside the upper electrode.

15. The electronic component according to claim 2, wherein
the capacitor dielectric film includes silicon nitride and covers a side surface of the lower electrode.

16. The electronic component according to claim 2, wherein
the platinum film has a thickness of about 5 nm or more.
